(19) United States
(12) Patent Application Publication
(10) Pub. No.: US 2026/0110963 A1
(43) Pub. Date: Apr. 23, 2026

(54) PHOTORESIST COMPOSITION, PATTERN FORMING METHOD USING NEAR-FIELD SURFACE LAYER IMAGING, AND DEPOSITION DEVICE

(71) Applicant: THE INSTITUTE OF OPTICS AND ELECTRONICS, THE CHINESE ACADEMY OF SCIENCES, Chengdu, Sichuan (CN)

(72) Inventors: Xiangang Luo, Chengdu, Sichuan (CN); Dongxu Yang, Chengdu, Sichuan (CN); Kaixin Su, Chengdu, Sichuan (CN); Zhihang Long, Chengdu, Sichuan (CN); Zeyu Zhao, Chengdu, Sichuan (CN); Ping Gao, Chengdu, Sichuan (CN)

(21) Appl. No.: 19/149,104

(22) PCT Filed: Jan. 2, 2024
(86) PCT No.: PCT/CN2024/070093

§ 371 Date: Jul. 18, 2025

(30) Foreign Application Priority Data
Jan. 20, 2023 (CN) 202310102886.X

(51) Int. Cl. G03F 7/027; C23C 16/04; C23C 16/44; C23C 16/46; C23C 16/52; G03F 7/00; G03F 7/004; G03F 7/36; G03F 7/38

(52) U.S. Cl. CPC G03F 7/027; C23C 16/04; C23C 16/4412; C23C 16/46; C23C 16/52; G03F 7/0045; G03F 7/0048; G03F 7/36; G03F 7/38; G03F 7/70325

(57) ABSTRACT

A photoresist composition, a pattern forming method using near-field surface layer imaging, and a deposition device. The photoresist composition comprises: a solvent; a molecular glass compound, which is a calixarene derivative grafted with diazonaphthoquinone and serves as a film-forming component and a photosensitive component; and an affinity inhibitor, which is at least used for protecting a hydroxyl group in the photoresist composition, so as to improve the contrast ratio of an exposure area and a non-exposure area during the formation of a pattern. The photoresist composition can be exposed within the full thickness range of the photoresist by means of near-field photolithography, thereby achieving high-resolution imaging.

The present disclosure claims the priority to the Chinese patent application with the filing No. 202310102886.X, filed on Jan. 20, 2023, the contents of which are incorporated herein by reference in entirety.

### TECHNICAL FIELD

The present disclosure relates to the technical field of photoresists, and specifically to a photoresist composition, a pattern forming method using near-field surface layer imaging and a deposition device.

### BACKGROUND ART

Near-field photolithography can break through technical dilemma of current optical lithography resolution limit, and realizes super-resolution exposure using long-wavelength light sources (for example, I-line light sources with a wavelength of 365 nm). However, due to characteristics of evanescent waves, an evanescent field transfer depth carrying high-frequency information can only cover a photoresist film layer thickness under 5-10 nm (depending on resolution). A thin film layer photoresist is prone to defects such as pinholes, and increases the difficulty of etching process. For this problem, researchers have found that using a special film layer structure (metal enhancement layer) to enable the evanescent waves to excite surface plasmon realizing transfer thereof in a photoresist layer. Although this strategy can enhance an exposure depth and etch resistance to some extent, improvement on a practical thickness of photoresists remains limited, still falling obvious short of requirements of commercial photoresists. In addition, many problems such as poor adhesion of photoresists on metal substrates, screening of surface modification materials, and additional metal layer dry etching process also prevents acquisition and practical application of high-resolution patterns. Therefore, in order to obtain the super-resolution advantage of near-field lithography, it is necessary to develop a brand new surface imaging process, so that evanescent waves rapidly decaying on the surface layer can be fully utilized.

The existing near-field lithography technologies mainly have the following problems: 1. an exposure depth of focus is too shallow to realize full-depth exposure for sufficiently thick photoresist, and only ultra-thin photoresist film layers can be used; 2. ultra-thin photoresist film layers are prone to film-forming quality problems, and can hardly realize subsequent etching transfer processes; and 3. non-uniform distribution of optical field intensity and contrast within a photoresist layer depth range causes poor sidewall verticality after photoresist development.

Herein, conventional polymeric photoresists also have certain drawbacks: 1. because the conventional polymeric photoresists have a too large molecular volume, obtained photolithographic patterns typically have poor line edge/width roughness; and 2. most conventional polymeric photoresists have a relatively strong affinity adsorption capacity with a hard mask precursor material, and a non-exposure region also have a certain thickness of deposition in a hard mask deposition process, thus degrading final imaging contrast.

### SUMMARY

### (I) Technical Problems to be Solved

With regard to the above problems, the present disclosure provides a photoresist composition, a pattern forming method using near-field surface layer imaging and a deposition device, for solving the technical problems in conventional near-field lithography, such as short depth of focus of photoresists and inability to expose photoresists within a full thickness range.

### (II) Technical Solutions

In one aspect, the present disclosure provides a photoresist composition, including: a solvent; a molecular glass compound, which is a calixarene derivative grafted with diazonaphthoquinone and acts as a film-forming component and a photosensitive component; and an affinity inhibitor, at least for protecting hydroxyl groups in the photoresist composition, so as to improve contrast between an exposure region and a non-exposure region during pattern formation.

Further, the molecular glass compound is 1,3-dihydroxycalix[4] arene-methyl grafted with diazonaphthoquinone; a grafting rate of diazonaphthoquinone in the molecular glass compound is 37.5%-50%; and a molecular weight of the molecular glass compound is 1,200-1,500.

Further, structural formula of the molecular glass compound is following Formula I:

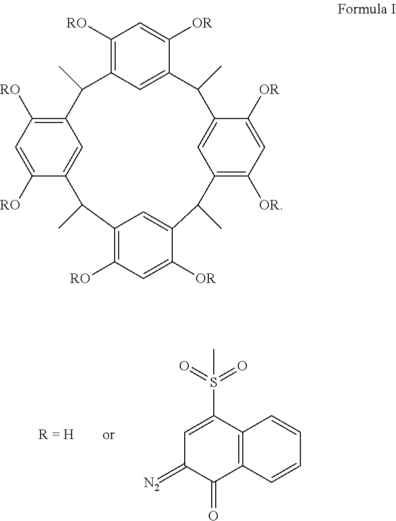

Further, the affinity inhibitor is triphenol A grafted with diazonaphthoquinone; a grafting rate of diazonaphthoquinone in the affinity inhibitor is 70%-100%; and a molecular weight of the affinity inhibitor is 900-1,200.

Further, structural formula of the affinity inhibitor is following Formula II:

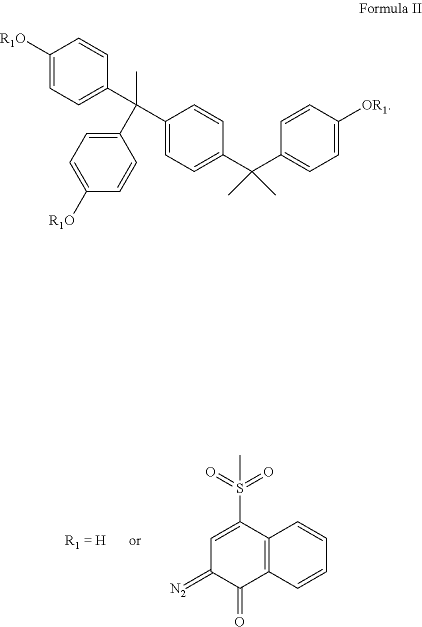

Further, the molecular glass compound and the affinity inhibitor account for 2.5%-5% by mass of the photoresist composition, where a mass of the affinity inhibitor is 10%-100% of that of the molecular glass compound.

Further, the solvent includes one or a mixture of more of propylene glycol methyl ether acetate, n-butyl acetate, ethyl acetate, γ-butyrolactone and propylene glycol methyl ether.

In another aspect, the present disclosure provides a pattern forming method using near-field surface layer imaging, including: S1, coating the preceding photoresist composition on a substrate to form a photoresist layer, where the photoresist layer includes the molecular glass compound, the affinity inhibitor and the solvent; S2, exposing the photoresist layer by means of the near-field lithography, where a surface layer of the photoresist layer in an exposure region undergoes photosensitive curing; S3, selectively depositing a hard mask precursor on the photoresist layer, heating to enable the hard mask precursor in the exposure region to be bound with the photoresist layer, while the affinity inhibitor inhibiting binding of the hard mask precursor in a non-exposure region with the photoresist layer; S4, performing mild etching on the photoresist layer after deposition, so as to remove residual organic matters in the exposure region and oxidize the hard mask precursor deposited on the exposure region to form a hard mask layer; and S5, subjecting the photoresist layer to deep etching, to selectively etch away the photoresist layer in the non-exposure region, which is not protected by the hard mask layer, so as to obtain a high-resolution imaged pattern.

Further, after the S2, the method further includes: S21, performing baking on the photoresist layer, to enable the photoresist layer in the non-exposure region to undergo a cross-linking reaction, so as to further inhibit binding of the hard mask precursor in the non-exposure region with the photoresist layer in S3, where a baking temperature is 120-145° C., and a baking duration is 1-5 min.

Further, after the S4, the method further includes: S41, etching to remove residual hard mask precursor in the non-exposure region and superfluous hard mask layer.

Further, a method for selectively depositing the hard mask precursor on the photoresist layer in the S3 includes a vapor phase deposition method and a liquid phase deposition method; the hard mask precursor is a silicon-based material or a metal-based material, preferably one or a mixture of more of titanium chloride, titanium isopropoxide, tetrakis(dimethylamino) hafnium, tetrakis(methylelamino) zirconium, dimethylsilyl dimethylamine, trimethylsilyl dimethylamine, trimethylsilyl diethylamine, 2,2,4,4,6,6-hexamethylcyclotrimethylazane, 1,1,3,3,5,5-hexamethylcyclotriosiloxane and bis(dimethylamino)dimethylsilane.

In a further aspect, the present disclosure provides a vapor phase hard mask deposition device, including: a main chamber body, having a relatively airtight sample chamber, where the sample chamber's intra-chamber volume is controlled through a position-adjustable cover plate; and the sample chamber accommodates the substrate obtained according to the preceding S2; a liquid supply unit, containing a hard mask precursor, where a liquid inlet pipe of the liquid supply unit extends into the sample chamber; a liquid inlet control unit, provided on the liquid inlet pipe of the liquid supply unit and configured to control entry of the hard mask precursor into the sample chamber, wherein the hard mask precursor is evaporated in the sample chamber and then deposited on the substrate containing a photoresist layer; a heating unit, configured to heat the substrate containing the photoresist layer during deposition; and a gas regulation unit, including a gas intake assembly for introducing a displacement gas and a gas exhaust assembly for evacuating and removing waste gases.

### (III) Beneficial Effects

For the photoresist composition, the pattern forming method using near-field surface layer imaging and the deposition device of the present disclosure, the molecular glass compound is used for forming the film, acts as a primary photosensitive component, and provides hydroxyl sites for deposition of the hard mask precursor in the exposure region; and the affinity inhibitor is used for protecting the hydroxyl groups in the photoresist composition, and may further undergo thermal crosslinking with the molecular glass compound, to synergistically reduce attachment of the non-exposure region to the hard mask precursor. Using the photoresist composition for near-field lithography, and using the hard mask precursor for forming the hard mask layer in the exposure region, exposure can be performed within a full thickness range of the photoresist, thus realizing high-resolution pattern imaging.

### BRIEF DESCRIPTION OF DRAWINGS

FIG. 1 schematically shows a flowchart of a pattern forming method using near-field surface layer imaging according to embodiments of the present disclosure;

FIG. 2 schematically shows a schematic diagram of a lithography principle according to embodiments of the present disclosure;

FIG. 3 schematically shows a complete process flowchart of the pattern forming method using near-field surface layer imaging according to embodiments of the present disclosure;

FIG. 4 schematically shows a structural schematic view of a vapor phase hard mask deposition device according to embodiments of the present disclosure;

FIG. 5 schematically shows a 64 nm half-pitch pattern obtained according to Example 1 of the present disclosure;

FIG. 6 schematically shows a 64 nm half-pitch pattern obtained according to Example 2 of the present disclosure;

FIG. 7 schematically shows a 44 nm half-pitch pattern obtained according to Example 2 of the present disclosure; and

FIG. 8 schematically shows a 64 nm half-pitch pattern obtained according to Comparative Example 1 of the present disclosure.

### DETAILED DESCRIPTION OF EMBODIMENTS

In order to make objectives, technical solutions and advantages of the present disclosure more clear and understandable, the present disclosure is further described in detail below in conjunction with embodiments with reference to drawings.

The terms used herein are merely for the purpose of describing the embodiments, and are not intended to limit the present disclosure. The terms such as “include” and “contain” used herein indicate existence of the features, steps, operations and/or components, but do not exclude existence or addition of one or more other features, steps, operations or components.

All the terms (including technical and scientific terms) used herein have the meanings as commonly understood by those skilled in the art, unless otherwise defined. It should be noted that the terms used herein should be interpreted as having meanings that are consistent with the context of the present description, and should not be interpreted in an idealized or overly formal manner.

The present disclosure provides a photoresist composition, including: a solvent; a molecular glass compound, which is a calixarene derivative grafted with diazonaphthoquinone and acts as a film-forming component and a photosensitive component; and an affinity inhibitor, at least for protecting hydroxyl groups in the photoresist composition, so as to improve contrast between an exposure region and a non-exposure region during pattern formation.

The photoresist composition of the present disclosure includes the molecular glass compound, the affinity inhibitor and the solvent. Herein, the molecular glass compound selects the calixarene derivative with excellent film-forming performance and uniform molecular weight distribution as the film-forming component and the grafted diazonaphthoquinone as the photosensitive component, and provides hydroxyl sites for deposition of a hard mask precursor in the exposure region during pattern formation. On one hand, the affinity inhibitor protects hydroxyl groups in the photoresist composition through weak interactions such as hydrogen bonding, prevents the hydroxyl groups from being exposed, regulates a content of hydroxyl groups in the non-exposure region, and reduces affinity of the photoresist composition with the hard mask precursor. On the other hand, the affinity inhibitor may further undergo thermal crosslinking with the molecular glass compound, and synergistically reduce attachment of the non-exposure region to the hard mask precursor. The molecular glass compound and the affinity inhibitor act synergistically and are indispensable.

Based on the above embodiments, the molecular glass compound is 1,3-dihydroxycalix[4] arene-methyl grafted with diazonaphthoquinone; a grafting rate of diazonaphthoquinone in the molecular glass compound is 37.5%-50%; and a molecular weight of the molecular glass compound is 1,200-1,500.

Preferably, the molecular glass compound is 1,3-dihydroxycalix[4] arene-methyl grafted with diazonaphthoquinone, with structural formula thereof as shown in Formula I:

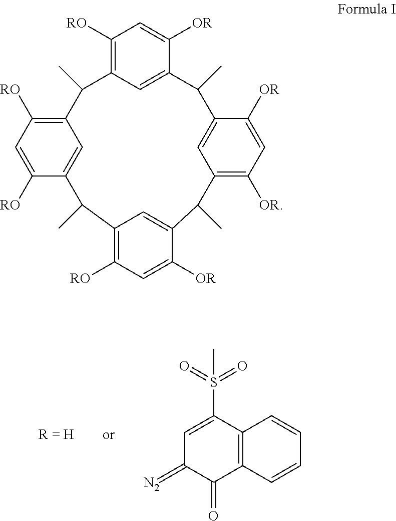

Based on the above embodiment, the affinity inhibitor is triphenol A grafted with diazonaphthoquinone; the grafting rate of diazonaphthoquinone in the affinity inhibitor is 70%-100%; and the molecular weight of the affinity inhibitor is 900-1,200.

Preferably, the affinity inhibitor is triphenol A grafted with diazonaphthoquinone, with structural formula thereof as shown in Formula II:

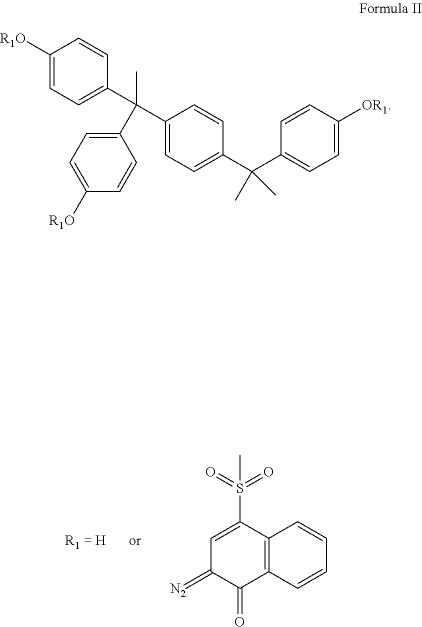

A high grafting rate of diazonaphthoquinone in the affinity inhibitor is beneficial for inhibiting the hydroxyl groups in the system, and enhancing chemical contrast between the exposure region and the non-exposure region.

Based on the above embodiment, the molecular glass compound and the affinity inhibitor account for 2.5%-5% by mass of the photoresist composition, where a mass of the affinity inhibitor is 10%-100% of that of the molecular glass compound.

Preferably, a mass percentage of the molecular glass compound and the affinity inhibitor is 2.5%-5%, and the solvent may account for 94%-97.5% by mass of the photoresist composition. In addition, other additive ingredients can be optionally added to the photoresist composition, including one or a mixture of more of a dissolution promoting agent, a leveling agent, a surfactant, and a stabilizer, with a total mass percentage thereof not exceeding 1%. The ratio is an optimized value for forming an ultra-thin film layer below 100 nm. If a solvent content is too low, it is difficult to form the ultra-thin film layer via spin coating (at a spin coating speed of 1,500-4,000 rpm). If the solvent content is too high, the photoresist composition is too dilute to form a high-quality photoresist film layer. A mass ratio of the molecular glass compound and the affinity inhibitor within the above range can enable relatively high chemical contrast between the exposure region and the non-exposure region, thereby ensuring formation of a high-resolution pattern.

Based on the above embodiment, the solvent includes one or a mixture of more of propylene glycol methyl ether acetate, n-butyl acetate, ethyl acetate, γ-butyrolactone and propylene glycol methyl ether.

The solvent can enable the photoresist composition to be in a liquid state so as to facilitate coating, and the other components are mixed with the solvent to form the photoresist composition. The above solvents have relatively good coverage for various photoresist components with different dissolution polarities.

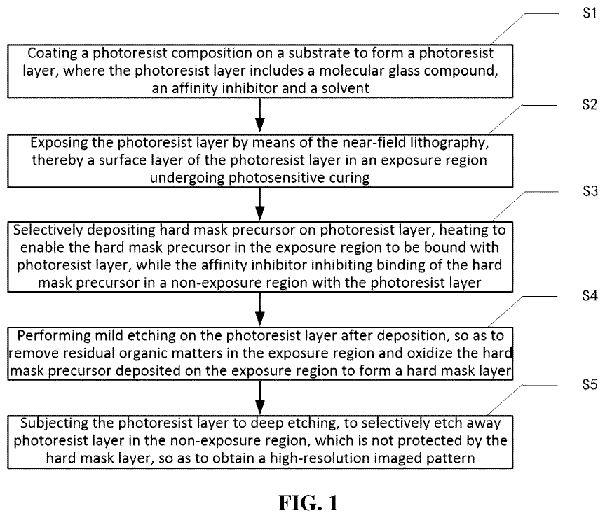

The present disclosure further provides a pattern forming method using near-field surface layer imaging. With reference to FIG. 1, the method includes: S1, coating a photoresist composition on a substrate to form a photoresist layer, where the photoresist layer includes a molecular glass compound, an affinity inhibitor and a solvent; S2, exposing the photoresist layer by means of the near-field lithography, thereby a surface layer of the photoresist layer in an exposure region undergoing photosensitive curing; S3, selectively depositing a hard mask precursor on the photoresist layer, heating to enable the hard mask precursor in the exposure region to be bound with the photoresist layer, while the affinity inhibitor inhibiting binding of the hard mask precursor in a non-exposure region with the photoresist layer; S4, performing mild etching on the photoresist layer after deposition, so as to remove residual organic matters in the exposure region and oxidize the hard mask precursor deposited on the exposure region to form a hard mask layer; and S5, subjecting the photoresist layer to deep etching, to selectively etch away the photoresist layer in the non-exposure region, which is not protected by the hard mask layer, so as to obtain a high-resolution imaged pattern.

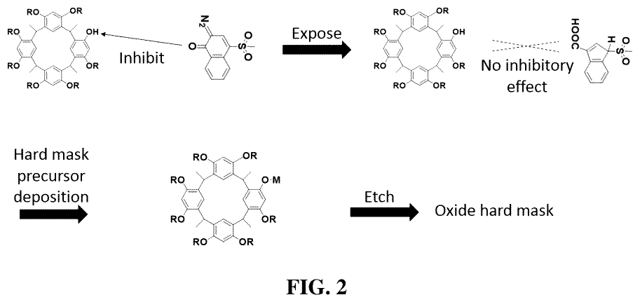

The present disclosure utilizes the characteristics of near-field lithography to perform high-resolution exposure on the surface of the photoresist composition. The lithography principle is as shown in FIG. 2. Because the hydroxyl contents of the photoresist composition in the exposure region and the non-exposure region are significantly different, a specific hard mask precursor can be used to react with the hydroxyl groups in the hydroxyl-rich exposure region, so as to incorporate the hard mask precursor into the exposure region of the photoresist composition. Then the photoresist composition in the non-exposure region is selectively etched away by oxygen plasma so as to obtain the pattern.

Herein, in a mild etching stage with oxygen plasma, the hard mask precursor in the exposure region of the photoresist composition will be oxidized on the surface of the photoresist composition to form an oxide hard mask layer (such as silicon oxide, titanium oxide, and hafnium oxide), and the oxide hard mask layer can prevent further etching of the underlying photoresist composition, while the non-exposure region, containing only organic components, is rapidly etched away, thereby forming a lithographic pattern. Although the method is applicable to multiple hydroxyl-containing photoresist systems and multiple hard mask precursors in principle, only specific material combinations combined with specific process steps can form pattern image with nanoscale resolution.

The pattern forming method of the present disclosure can break through the diffraction limit of optical lithography, while achieving super-resolution imaging, and can also solve the problems of short depth of focus of the near-field lithography and inability to expose the photoresist within the full thickness range through combination with the hard mask layer.

Based on the above embodiments, after S2, the method further includes: S21, performing baking on the photoresist layer, to enable the photoresist layer in the non-exposure region to undergo a cross-linking reaction, thereby further inhibiting the binding of the hard mask precursor in the non-exposure region with the photoresist layer in S3, where a baking temperature is 120-145° C., and a baking duration is 1-5 min.

Based on the above embodiments, after S4, the method further includes: S41, etching to remove residual hard mask precursor in the non-exposure region and superfluous hard mask layer.

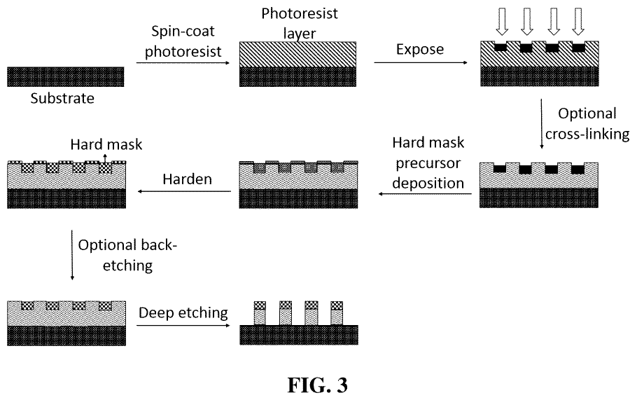

A complete process flowchart of the pattern forming method of the present disclosure, as shown in FIG. 3, includes following steps:
S1, preparation of the photoresist layer: forming the photoresist layer on the substrate using the photoresist composition provided by the present disclosure, where the photoresist composition is spin-coated at a rotational speed of 1,500-4,000 rpm, followed by pre-baking at 90-110° C. for 30-180 s, thus rendering a film thickness of 30-120 nm, where the film thickness is preferably 60-90 nm, and the film thickness is more preferably 70-80 nm;
S2, exposure: exposing a mask having a nanoscale pattern in proximity with the photoresist layer by means of near-field lithography, in which case, due to the rapid decaying characteristic of evanescent waves, the photoresist layer can only be photosensitive at a surface layer of 5-10 nm (depending on pattern size and film layer structure), and a photosensitive part undergoes a chemical reaction, to expose a significant amount of hydroxyl groups;
S21, optional cross-linking reaction: optionally, performing baking on the photoresist layer to enable a diazonaphthoquinone (including diazonaphthoquinone on the molecular glass compound and diazonaphthoquinone on the affinity inhibitor) structure in the non-exposure region and the hydroxyl groups to undergo a certain cross-linking reaction, thereby further weakening interaction between the non-exposure region and the hard mask precursor; and in the exposure region, a degree of cross-linking being much lower than that in the non-exposure region due to massive conversion of the diazonaphthoquinone structure, where a baking temperature of the cross-linking reaction is 120-145° C., and a baking duration is 1-5 min;
S3, hard mask deposition: placing the substrate containing the photoresist layer in an environment containing the hard mask precursor to undergo selective deposition, and under appropriate heating conditions, enabling the hard mask precursor to selectively bond with the hydroxyl groups in the exposure region;
S4, mild etching and hardening: performing mild etching on the photoresist layer with oxygen plasma, etc. after deposition, so as to remove organic matters in the exposure region upon treatment with the hard mask precursor and form the hard mask layer on the surface;
S41, optional back-etching: since there will be inevitably a small amount of hard mask deposition in the non-exposure region, optionally performing back-etching on the photoresist layer using a halogen-containing atmosphere, so as to remove residual hard mask precursor in the non-exposure region and superfluous hard mask layer; and
S5, deep etching: subjecting the photoresist layer to deep etching using the oxygen plasma, etc., and obtaining the pattern by selectively etching away the photoresist layer, which is not protected by the hard mask layer, where the etching employs an oxygen flow rate of 5-10 sccm, power of 5-10 W, and a duration of 120-300 s.

The pattern forming method of the present disclosure realizes the high-resolution pattern imaging by screening and regulating a photoresist material, a hard mask precursor material and a process. At the same time, the problems of a too small exposure depth of focus and thin film layer photoresist defects in the near-field lithography are solved by the surface imaging. The method of the present disclosure is applicable to near-field lithography, and can realize high-resolution pattern imaging below 50 nm using long-wavelength ultraviolet light sources.

Based on the above embodiments, a method for selectively depositing the hard mask precursor on the photoresist layer in S3 includes a vapor phase deposition method and a liquid phase deposition method. The hard mask precursor is a silicon-based material or a metal-based material.

The hard mask precursor may be a silicon-based material or a metal-based material, including but not limited to one of titanium chloride, titanium isopropoxide, tetrakis(dimethylamino) hafnium, tetrakis(methylelamino) zirconium, dimethylsilyl dimethylamine, trimethylsilyl dimethylamine, trimethylsilyl diethylamine, 2,2,4,4,6,6-hexamethylcyclotrimethylazane (HMCTS), 1,1,3,3,5,5-hexamethylcyclotriosiloxane and bis(dimethylamino)dimethylsilane. HMCTS is preferable in view of the pattern quality (compactness of resulting pattern) and solubility of the hard mask precursor to the photoresist.

The method for selective deposition includes the vapor phase deposition method and the liquid phase deposition method as follows.

Vapor phase deposition method: placing the substrate containing the photoresist layer obtained in step S2 or step S21 in a vapor deposition device, after evacuating a chamber, preheating at 100-120° C. for 2-8 min, introducing the hard mask precursor, maintaining temperature at 100-120° C., standing for 10-20 min to allow full reaction between the photoresist layer and the hard mask precursor, performing evacuation again, removing residual gases, performing gas washing with nitrogen for 2-3 times, and then taking out a sample.

Liquid phase deposition method: a liquid phase composition includes the hard mask precursor, a diffusion promoter (a resin solvent) and a resin nonsolvent, where the diffusion promoter may be propylene glycol methyl ether acetate or N-methylpyrrolidone, and the resin nonsolvent may be o-xylene, m-xylene or p-xylene; the hard mask precursor accounts for 5-15% by weight of the liquid phase composition, the diffusion promoter accounts for no more than 5% by weight of the liquid phase composition, and the resin non-solvent accounts for 80-95% by weight of the liquid phase composition. The liquid phase deposition is performed at a temperature of 25-40° C. for duration of 0.5-2 min.

The present disclosure further provides a vapor phase hard mask deposition device, including: a main chamber body having a relatively airtight sample chamber, where the sample chamber's intra-chamber volume is controlled through a position-adjustable cover plate; the sample chamber accommodates the substrate obtained according to the above S2; a liquid supply unit, containing a hard mask precursor, a liquid inlet pipe of the liquid supply unit extending into the sample chamber; a liquid inlet control unit, provided on the liquid inlet pipe of the liquid supply unit and configured to control entry of the hard mask precursor into the sample chamber, where the hard mask precursor is evaporated in the sample chamber and then deposited on the substrate containing a photoresist layer; a heating unit, configured to heat the substrate containing the photoresist layer during deposition; and a gas regulation unit, including a gas intake assembly for introducing a displacement gas and a gas exhaust assembly for evacuating and removing waste gases.

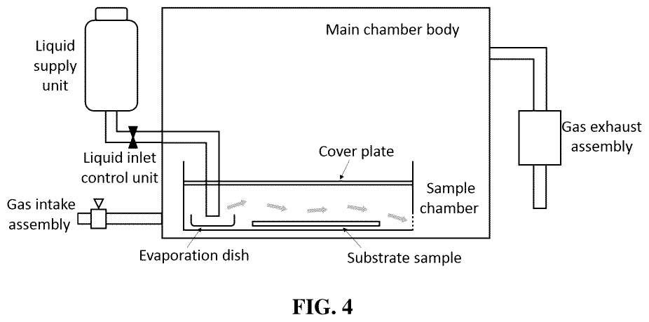

As shown in FIG. 4, the liquid supply unit is located outside the main chamber body and is made of a stainless steel material (or quartz); the liquid inlet pipe in the main chamber body is made of a quartz material, with a tail portion bent downwards, a bottom of the liquid inlet pipe is a liquid outlet, and the liquid inlet pipe is provided with the liquid inlet control unit (for example, a liquid inlet valve), which is automatically opened when a liquid enters the chamber for controlling entry of the hard mask precursor into the vacuum main chamber body; an evaporation dish and a substrate sample (the substrate containing the photoresist layer) are placed in the sample chamber, the liquid outlet is provided above the evaporation dish, and the volume of the sample chamber can be controlled by the position-adjustable cover plate (so as to control a vapor concentration of a sample surface); and the heating unit (not shown) is configured to heat the substrate, the gas intake assembly is configured to introduce the displacement gas such as nitrogen for gas washing, and the gas exhaust assembly is configured to perform evacuation and remove waster gases.

An operation process of the mechanism is as follows:
(1) when a vacuum degree and a temperature in the main chamber body reach set values, the system automatically opens the liquid inlet control unit. Due to vacuum effect, the hard mask precursor is drawn into the main chamber body (with controlled flow rate), and is completely vaporized on the evaporation dish below the quartz liquid outlet;
(2) as a vaporization platform and the substrate sample are placed in a relatively closed space (i.e. the sample chamber), a higher gas concentration is obtained than other positions of the chamber, which is more conducive to performing a surface treatment on the substrate sample;
(3) both the liquid inlet pipe and the sample chamber are made of a quartz material, which is beneficial for observing an effect of a treatment process; and
(4) in a later process of gas displacement of the gas intake assembly, residual liquid vapor is completely displaced through the gas exhaust assembly (for example, a vacuum pump), including residual vapor within a quartz tube.

The pattern forming method of the present disclosure can effectively use the near-field lithography to perform imaging on a high-resolution optical field at a surface layer of the photoresist layer. Since the method does not require exposure in the full thickness range of the photoresist, a theoretical thickness of the photoresist used in the method can be arbitrarily large, thereby effectively solving the problem of short depth of focus of near-field lithography, and expanding the process window. At the same time, the hard mask precursor material and process are optimized, achieving an effect of highly selective deposition for the exposure region and the non-exposure region; the photoresist composition material system and process are optimized, thereby maximizing a hydroxyl concentration gradient in the exposure region and the non-exposure region, and elevating the resolution to an unprecedented level; the etching process is optimized, and transmission of the hard mask layer on a surface over the whole photoresist layer thickness is achieved, thereby solving the problem that the near-field lithography fails to expose on thick photoresists.

The present disclosure is further described below with reference to embodiments. The photoresist composition, the pattern forming method using near-field surface layer imaging and the deposition device are described in detail in the following examples. However, the following examples are merely illustrative of the present disclosure, while the scope of the present disclosure is not limited thereto.

The photoresist composition of the present disclosure includes: a molecular glass compound, which is 1,3-dihydroxycalix[4] arene-methyl grafted with 37.5%-50% of diazonaphthoquinone, and has a molecular weight of 1,200-1,500, with structural formula being as shown in Formula I; an affinity inhibitor, which is triphenol A grafted with 70%-100% of diazonaphthoquinone, and has a molecular weight of 900-1,200, with structural formula as shown in Formula II; and a solvent, which is one or a mixture of more of propylene glycol methyl ether acetate, n-butyl acetate, ethyl acetate, γ-butyrolactone and propylene glycol methyl ether.

The pattern forming method using near-field surface layer imaging of the present disclosure, as shown in FIG. 1 and FIG. 3, includes following sequential steps:
step 1, spin-coating the above photoresist composition on a substrate at a rotational speed of 1,500-4,000 rpm, and followed by pre-baking at 90-110° C. for 30-180 s, so as to render a photoresist layer with a film thickness of 30-120 nm, equivalent to the above step S1;
step 2, exposing a mask having a nanoscale pattern in proximity with the photoresist layer using near-field lithography, where the photoresist layer can be photosensitive at a surface layer of 5-10 nm, equivalent to the above step S2;
step 21, optionally, performing baking on the photoresist layer to enable a diazonaphthoquinone (including diazonaphthoquinone on the molecular glass compound and diazonaphthoquinone on the affinity inhibitor) structure in a non-exposure region and hydroxyl groups to undergo a certain cross-linking reaction, thereby further inhibiting binding of the hard mask precursor in the non-exposure region in S3 with the photoresist layer, equivalent to the above step S21;
step 3, selectively depositing the hard mask precursor on the photoresist layer, and heating to enable the hard mask precursor in the exposure region to bind with the photoresist layer, equivalent to the above step S3;
step 4, performing mild etching on the photoresist layer with oxygen plasma after deposition, so as to remove residual organic matters in the exposure region and oxidize the hard mask precursor deposited on the exposure region to form the hard mask layer, equivalent to the above step S4;
step 41, optionally, etching to remove the residual hard mask precursor in the non-exposure region and superfluous hard mask layer, equivalent to the above step S41; and
step S5, subjecting the photoresist layer to deep etching using the oxygen plasma, and selectively etching away the photoresist layer in the non-exposure region, which is not protected by the hard mask layer, so as to obtain a high-resolution imaged pattern, equivalent to the above step S5.

According to the above photoresist composition and pattern forming steps 1-5, six specific examples and three comparative examples are provided below.

### Example 1

A photoresist composition of the present example included a molecular glass compound with a grafting rate of 37.5%, a triphenol A affinity inhibitor with a grafting rate 70% of diazonaphthoquinone, and a PGMEA solvent, where the molecular glass compound and the affinity inhibitor accounted for 2.5% by mass of the photoresist composition, and a mass of the affinity inhibitor was 50% of that of the molecular glass compound.

A pattern forming method of the present example included following implementation steps:
step 1-1, preparing a photoresist layer with a thickness of about 30 nm on an Si substrate by spin coating at a spin-coating speed of 1,500 rpm for a duration of 30 s, and performing pre-baking on a 90° C. hot plate for 30 s, rendering a sample containing the photoresist layer;
step 1-2, exposing the sample by a near-field lithography machine with a central wavelength of 365 nm, where a mask pattern was a grating with a half pitch of 64 nm, and an exposure dose was about 40 mJ/cm²;
step 1-3, placing the sample in a deposition solution, where the solution contained: bis(dimethylamino)dimethylsilane, propylene glycol methyl ether acetate and o-xylene (where weight percentages of the three components were 5%, 3% and 92%, respectively); soaking at a temperature of 30° C. for 2 min; and finally gently rinsing a sample surface with o-xylene, and blow-drying with a nitrogen gun;
step 1-4, performing mild etching on the photoresist layer with oxygen plasma after deposition, where etching power was 10 W, a chamber pressure was 1 Pa, a sample holder temperature was 10° C., and an etching duration was about 30 s; and
step 1-5, subjecting the photoresist layer to deep etching with oxygen plasma, where an etching duration was about 120 s, power was 5 W, and an oxygen flow rate was 5 sccm.

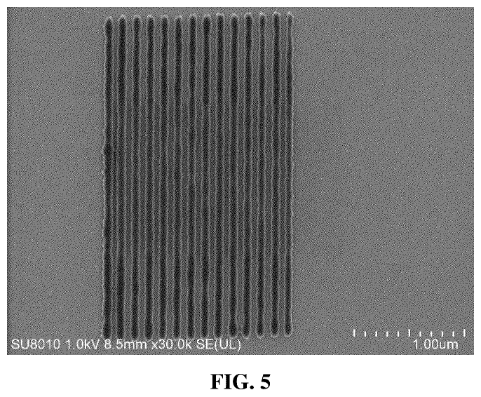

FIG. 5 is a 64 nm half-pitch pattern obtained in Example 1, and it can be seen from the pattern that lines are relatively distinct, outlines are clear, and edges are slightly rough.

### Example 2

A photoresist composition of the present example included a molecular glass compound with a grafting rate of 37.5%, a triphenol A affinity inhibitor with a grafting rate 100% of diazonaphthoquinone, and a PGMEA solvent, where the molecular glass compound and the affinity inhibitor accounted for 3.8% by mass of the photoresist composition, and a mass of the affinity inhibitor was 100% of that of the molecular glass compound.

A pattern forming method of the present example included following implementation steps:
step 2-1, preparing a photoresist layer with a thickness of about 65 nm on an Si substrate by spin coating at a spin-coating speed of 4,000 rpm for a duration of 30 s, and performing pre-baking on a 100° C. hot plate for 120 s, taking out the substrate and then cooling to room temperature, rendering a sample containing the photoresist layer;
step 2-2, exposing the sample by a near-field lithography machine with a central wavelength of 365 nm, where a mask pattern was a grating with a half pitch of 44 nm and 64 nm, respectively, and an exposure dose was about 72 mJ/cm²;
step 2-21, subsequently baking on a 120° C. hot plate for 2 min;
step 2-3, placing the sample in a vapor phase hard mask deposition device shown in FIG. 4, where an atmosphere in the device was a vacuum environment, and the sample was treated with an HMCTS hard mask precursor at a temperature of 110° C. for 15 min;
step 2-4, performing mild etching on the photoresist layer with oxygen plasma after deposition, where etching power was 10 W, a chamber pressure was 1 Pa, a sample holder temperature was 10° C., and an etching duration was about 30 s; and
step 2-41, performing back-etching on the photoresist layer with a mixture of trifluoromethane plasma (25 sccm) and sulfur hexafluoride plasma (5 sccm) in a volume ratio of 5:1, where an etching duration was about 30 s, a vacuum degree was 7×10⁻³ Pa, and a chamber pressure was 1 Pa; and
step 2-5, finally subjecting the photoresist layer to deep etching with oxygen plasma, where an etching duration was about 200 s, power was 10 W, and an oxygen flow rate was 10 sccm.

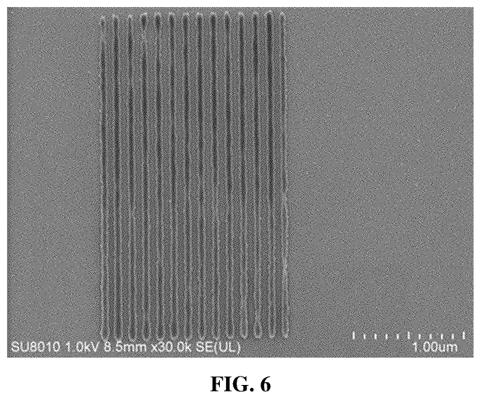

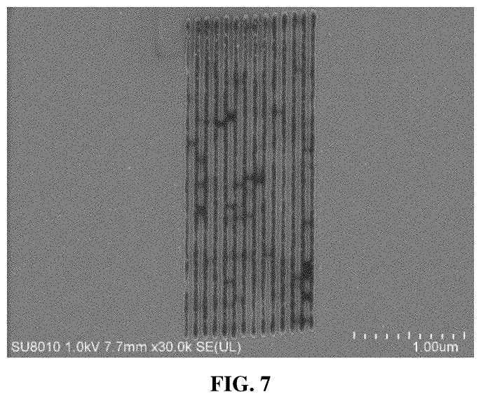

FIG. 6 is a 64 nm half-pitch pattern obtained in Example 2, where there is no residual photoresist around lines, and the lines are distinct and smooth. FIG. 7 is a 44 nm half-pitch pattern obtained in Example 2, with clear and uniform lines.

### Comparative Example 1

A photoresist composition of the present comparative example included a molecular glass compound with a grafting rate of 37.5% and a PGMEA solvent, where the molecular glass compound accounted for 3% by mass of the photoresist composition.

A pattern forming method of the present embodiment included following implementation steps:
step 3-1, preparing a photoresist layer with a thickness of about 65 nm on an Si substrate by spin coating at a spin-coating speed of 4,000 rpm for a duration of 30 s, and performing pre-baking on a 100° C. hot plate for 120 s, taking out the substrate and then cooling to room temperature, rendering a sample containing the photoresist layer;
step 3-2, exposing the sample by a near-field lithography machine with a central wavelength of 365 nm, where a mask pattern was a grating with a half-pitch of 64 nm, and an exposure dose was about 72 mJ/cm²;
step 3-21, subsequently baking on a 120° C. hot plate for 2 min;
step 3-3, placing the sample in a vapor phase hard mask deposition device shown in FIG. 4, where an atmosphere in the device was a vacuum environment, and the sample was treated with an HMCTS hard mask precursor at a temperature of 110° C. for 15 min;
step 3-4, performing mild etching on the photoresist layer with oxygen plasma, where etching power was 10 W, a chamber pressure was 1 Pa, a sample holder temperature was 10° C., and an etching duration was about 30 s; and
step 3-41, performing back-etching on the photoresist layer with a mixture of trifluoromethane plasma (25 sccm) and sulfur hexafluoride plasma (5 sccm) in a volume ratio of 5:1, where an etching duration was about 30 s, a vacuum degree was 7×10⁻³ Pa, and a chamber pressure was 1 Pa; and
step 3-5, finally subjecting the photoresist layer to deep etching with oxygen plasma, where an etching duration was about 200 s, power was 10 W, and an oxygen flow rate was 10 sccm.

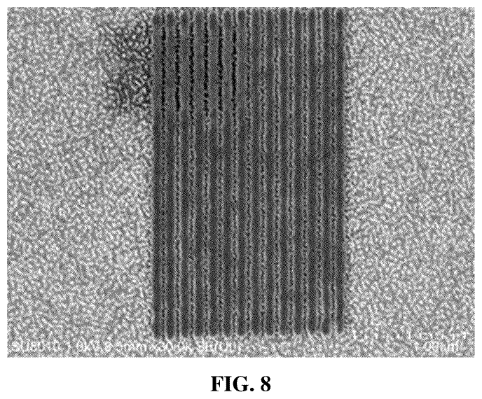

FIG. 8 is a 64 nm half-pitch pattern obtained in Comparative Example 1, in which cross-linking between lines is relatively obvious, line edges are rough, and residual photoresist is severe in a non-exposure region.

Similarly, experimental parameters and obtained pattern quality results in Example 3 to Example 6 and Comparative Example 2 to Comparative Example 3 are listed in the following table, and a specific procedure is not described herein again.

| | | | Total mass percentage of | | | | |
|---|---|---|---|---|---|---|---|
| | Molecular glass | Affinity inhibitor | molecular glass | | | | |
| | compound grafting rate | grafting rate and | compound and affinity | Cross- | | | |
| | and corresponding | corresponding | inhibitor and mass | linking | | Back-etching | Pattern |
| Sample | molecular weight | molecular weight | percentage of molecular | condition | Deposition condition | condition | quality |
| Example 1 | 37.5% | 70% | 2.5%, 50% | None | Liquid phase, | 0 | Good |
| | M = 1241.2 | M = 912.8 | | | bis(dimethylamino) | | |
| | | | | | dimethylsilane, | | |
| | | | | | 40° C., 2 min | | |
| Example 2 | 37.5% | 100% | 3.8%, 100% | 120° C., | Vapor phase, | 25 sccm CHF₃, | Excellent |
| | M = 1241.2 | M = 1120.2 | | 2 min | HMCTS, | 5 sccm SF₆, | |
| | | | | | 110° C. 15 min | 30 s | |
| Example 3 | 50% | 80% | 3.0%, 50% | 135° C., | Vapor phase, | 15 sccm CHF₃, | Excellent |
| | M = 1487.5 | M = 982.5 | | 2.5 min | HMCTS, | 15 sccm SF₆, | |
| | | | | | 115° C., 18 min | 60 s | |
| Example 4 | 50% | 90% | 2.5%, 30% | 145° C., | Vapor phase, | 5 sccm CHF₃, | Good |
| | M = 1487.5 | M = 1052.3 | | 5 min | dimethylsilyl | 25 sccm SF₆, | |
| | | | | | dimethylamine, | 90 s | |
| | | | | | 120° C., 20 min | | |
| Example 5 | 37.5% | 85% | 5.0%, 50% | None | Vapor phase, | 20 sccm CHF₃, | Good |
| | M = 1241.2 | M = 1017.4 | | | trimethylsilyl | 5 sccm SF₆, | |
| | | | | | dimethylamine, | 20 s | |
| | | | | | 100° C., 10 min | | |
| Example 6 | 50% | 95% | 3.0%, 50% | 135° C., | Liquid phase, | 5 sccm CHF₃, | Good |
| | M = 1487.5 | M = 1085.1 | | 3 min | trimethylsilyl | 25 sccm SF₆, | |
| | | | | | diethylamine, | 50 s | |
| | | | | | 40° C., 0.5 min | | |
| Comparative | 37.5% | Not added | — | 120° C., | Vapor phase, | 25 sccm CHF₃, | Poor |
| Example 1 | M = 1241.2 | | | 2 min | HMCTS, | 25 sccm SF₆, | |
| | | | | | 110° C., 15 min | 30 s | |
| Comparative | 37.5% | 100% | 3.0%, 50% | 200° C., | Vapor phase, | 15 sccm CHF₃, | Poor |
| Example 2 | M = 1241.2 | M = 1120.2 | | 10 min | HMCTS, | 15 sccm SF₆, | |
| | | | | | 120° C., 20 min | 120 s | |
| Comparative | 50% | 80% | 3.0%, 50% | None | Vapor phase, | 5 sccm CHF₃, | Poor |
| Example 3 | M = 1487.5 | M = 982.5 | | | HMCTS, | 25 sccm SF₆, | |
| | | | | | 65° C., 5 min | 60 s | |

Comparative Example 2 was used for comparing a case where the cross-linking temperature exceeded an upper limit (145° C.) of the above temperature range, and Comparative Example 3 was used for comparing a case where the temperature was lower than a lower limit (100° C.) of the above temperature range during the vapor phase deposition of the hard mask layer.

It can be seen from the above table that a final patterning outcome of the present disclosure requires matching between materials and corresponding process condition ranges for successful realization.

The above specific examples further describe the objectives, the technical solutions and the beneficial effects of the present disclosure in detail. It should be understood that the above-mentioned are merely for specific examples of the present disclosure, and are not intended to limit the present disclosure. Any amendments, equivalent replacements, improvements and so on made within the spirit and principle of the present disclosure should be covered within the scope of protection of the present disclosure.

1. A photoresist composition, comprising:
a solvent;
a molecular glass compound, which is a calixarene derivative grafted with diazonaphthoquinone and acts as a film-forming component and a photosensitive component; and
an affinity inhibitor, at least for protecting hydroxyl groups in the photoresist composition, so as to improve contrast between an exposure region and a non-exposure region during pattern formation.

2. The photoresist composition according to claim 1, wherein the molecular glass compound is 1,3-dihydroxycalix[4] arene-methyl grafted with diazonaphthoquinone;
a grafting rate of diazonaphthoquinone in the molecular glass compound is 37.5%-50%; and
a molecular weight of the molecular glass compound is 1,200-1,500.

3. The photoresist composition according to claim 2, wherein structural formula of the molecular glass compound is following Formula I:

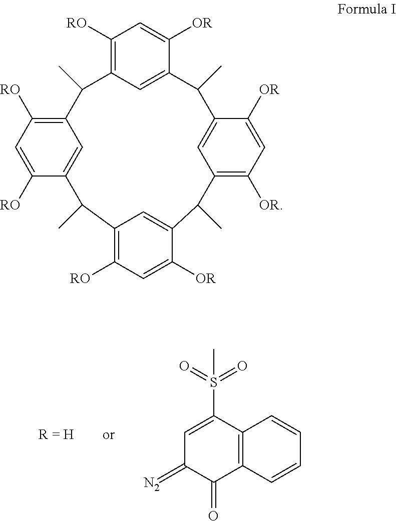

4. The photoresist composition according to claim 1, wherein the affinity inhibitor is triphenol A grafted with diazonaphthoquinone;
a grafting rate of diazonaphthoquinone in the affinity inhibitor is 70%-100%; and
a molecular weight of the affinity inhibitor is 900-1,200.

5. The photoresist composition according to claim 4, wherein structural formula of the affinity inhibitor is following Formula II:

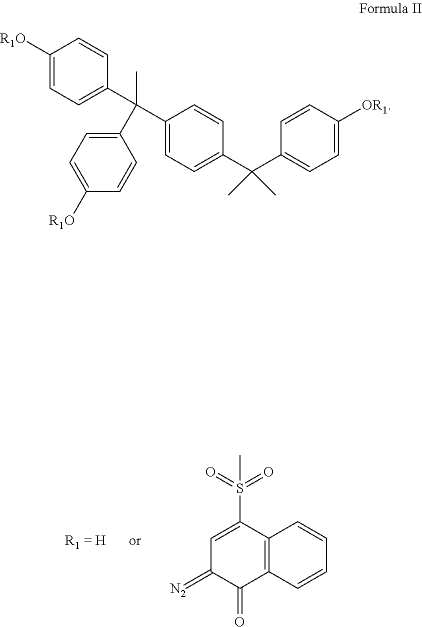

6. The photoresist composition according to claim 1, wherein the molecular glass compound and the affinity inhibitor account for 2.5%-5% by mass of the photoresist composition, wherein
a mass of the affinity inhibitor is 10%-100% of that of the molecular glass compound.

7. The photoresist composition according to claim 1, wherein the solvent comprises one or a mixture of more of propylene glycol methyl ether acetate, n-butyl acetate, ethyl acetate, γ-butyrolactone and propylene glycol methyl ether.

8. A pattern forming method using near-field surface layer imaging, comprising:
S1, coating the photoresist composition according to claim 1 on a substrate to form a photoresist layer, wherein the photoresist layer comprises the molecular glass compound, the affinity inhibitor and the solvent;
S2, exposing the photoresist layer by a near-field lithography, wherein a surface layer of the photoresist layer in an exposure region undergoes photosensitive curing;
S3, selectively depositing a hard mask precursor on the photoresist layer, heating to enable the hard mask precursor in the exposure region to be bound with the photoresist layer, while the affinity inhibitor inhibiting binding of the hard mask precursor in a non-exposure region with the photoresist layer;
S4, performing mild etching on the photoresist layer after deposition, so as to remove residual organic matters in the exposure region and oxidize the hard mask precursor deposited on the exposure region to form a hard mask layer; and
S5, subjecting the photoresist layer to deep etching, to selectively etch away the photoresist layer in the non-exposure region, which is not protected by the hard mask layer, so as to obtain a high-resolution imaged pattern.

9. The pattern forming method using the near-field surface layer imaging according to claim 8, wherein after the S2, the method further comprises:
S21, performing baking on the photoresist layer, to enable the photoresist layer in the non-exposure region to undergo a cross-linking reaction, so as to further inhibit binding of the hard mask precursor in the non-exposure region with the photoresist layer in S3, wherein
a baking temperature is 120-145° C., and a baking duration is 1-5 min.

10. The pattern forming method using the near-field surface layer imaging according to claim 8, wherein after the S4, the method further comprises:
S41, etching to remove residual hard mask precursor in the non-exposure region and superfluous hard mask layer.

11. The pattern forming method using the near-field surface layer imaging according to claim 8, wherein a method for selectively depositing the hard mask precursor on the photoresist layer in the S3 comprises a vapor phase deposition method and a liquid phase deposition method; and
the hard mask precursor is a silicon-based material or a metal-based material, preferably one or a mixture of more of titanium chloride, titanium isopropoxide, tetrakis(dimethylamino) hafnium, tetrakis(methylelamino) zirconium, dimethylsilyl dimethylamine, trimethylsilyl dimethylamine, trimethylsilyl diethylamine, 2,2,4,4,6,6-hexamethylcyclotrimethylazane, 1,1,3,3,5,5-hexamethylcyclotriosiloxane and bis(dimethylamino)dimethylsilane.

12. A vapor phase hard mask deposition device, comprising:
a main chamber body, having a relatively airtight sample chamber, wherein the sample chamber's intra-chamber volume is controlled through a position-adjustable cover plate; and the sample chamber accommodates a substrate obtained according to S2 in the pattern forming method using the near-field surface layer imaging according to claim 8;
a liquid supply unit, containing a hard mask precursor, wherein a liquid inlet pipe of the liquid supply unit extends into the sample chamber;
a liquid inlet control unit, provided on the liquid inlet pipe of the liquid supply unit and configured to control entry of the hard mask precursor into the sample chamber, wherein the hard mask precursor is evaporated in the sample chamber and then deposited on the substrate containing a photoresist layer;
a heating unit, configured to heat the substrate containing the photoresist layer during deposition; and
a gas regulation unit, comprising a gas intake assembly for introducing a displacement gas and a gas exhaust assembly for evacuating and removing waste gases.
